(19) United States
(12) Patent Application Publication
(10) Pub. No.: US 2026/0005125 A1
(43) Pub. Date: Jan. 1, 2026

(54) INVERTED GLASS INTERPOSER WITH GLASS STIFFENER

(71) Applicant: Intel Corporation, Santa Clara, CA (US)

(72) Inventors: Jeremy D. ECTON, Gilbert, AZ (US); Srinivas Venkata Ramanuja PIETAMBARAM, Chandler, AZ (US)

(21) Appl. No.: 18/758,049

(22) Filed: Jun. 28, 2024

(51) Int. Cl. H01L 23/498; H01L 23/00

(52) U.S. Cl. CPC H01L 23/49866; H01L 23/49827; H01L 23/49838; H01L 24/24; H01L 2224/24137; H01L 2224/24155; H01L 2924/15788; H01L 2924/17788

(57) ABSTRACT

Embodiments disclosed herein include an apparatus that comprises a first substrate that comprises a glass layer. In an embodiment, a plurality of vias are provided through a through a thickness of the first substrate. In an embodiment, a second substrate provided over a first surface of the first substrate, and the second substrate comprises an organic dielectric material. In an embodiment, a frame is provided over a second surface of the first substrate, and the frame may comprise a glass layer.

### BACKGROUND

The demand for miniaturization of form factor and increased levels of integration for high performance devices are driving sophisticated packaging approaches in the semiconductor industry. Die partitioning has enabled the scaling to smaller form factors without experiencing yield issues seen with other approaches. However, such die partitioning solutions rely on small die-to-die interconnect technologies. One die-to-die interconnect approach is the use of an interconnect bridge. Interconnect bridges have proven to be effective, but continued scaling may outpace the capabilities of the interconnect bridge. For example, high bump thickness variation (BTV) and bump-to-bump true positioning issues lead to challenges due to suboptimal dimensional stability of the organic core of the package substrate.

### BRIEF DESCRIPTION OF THE DRAWINGS

FIG. 1A is a cross-sectional illustration of a package substrate that includes a glass interposer with a reinforcement frame around the dies and a redistribution layer (RDL) on an opposite side of the glass interposer, in accordance with an embodiment.

FIG. 1B is a cross-sectional illustration of package substrate that includes a glass interposer with a reinforcement frame with a perimeter wall and an interior wall around the dies and a RDL on an opposite side of the glass interposer, in accordance with an embodiment.

FIG. 1C is a cross-sectional illustration of a package substrate that includes a glass interposer with a reinforcement frame around the dies that are coupled to the glass interposer by a solder, in accordance with an embodiment.

FIG. 1D is a cross-sectional illustration of a package substrate that includes a glass interposer with a reinforcement frame around the dies and a bridge in the RDL on the opposite side of the glass interposer, in accordance with an embodiment.

FIG. 1E is a cross-sectional illustration of a package substrate that includes a glass interposer with a reinforcement frame around the dies with an optical path through the glass interposer to a fiber array unit (FAU), in accordance with an embodiment.

FIG. 1F is a cross-sectional illustration of a large form factor package substrate that includes glass interposer with a reinforcement frame around the dies, in accordance with an embodiment.

FIGS. 2A-2G are illustrations depicting a process for forming a package substrate that includes a glass interposer with a reinforcement frame around the dies, in accordance with an embodiment.

FIGS. 3A-3E are cross-sectional illustrations depicting a process for forming a package substrate that includes a glass interposer with a reinforcement frame around the dies, where the reinforcement frame is fused to the glass interposer, in accordance with an embodiment.

FIGS. 4A-4C are cross-sectional illustrations depicting a process for forming a package substrate that includes a glass interposer with a reinforcement frame around the dies, in accordance with an embodiment.

FIG. 5 is a flow diagram of a process for forming a package substrate with a glass interposer and a reinforcement frame around the dies, in accordance with an embodiment.

FIG. 6 is a flow diagram of a process for forming a package substrate with a glass interposer that is fused to a reinforcement frame that surrounds the dies, in accordance with an embodiment.

FIG. 7 is a cross-sectional illustration of an electronic system with a package substrate that includes a glass interposer and a reinforcement frame around the dies, in accordance with an embodiment.

FIG. 8 is a schematic of a computing device built in accordance with an embodiment.

### EMBODIMENTS OF THE PRESENT DISCLOSURE

Described herein are package substrates with a glass interposer and a glass frame coupled to the glass interposer, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing die-to-die interconnect solutions are reaching their limit. For example, at bump pitches of approximately 25 μm or lower, the bump thickness variation (BTV) and/or bump-to-bump true position variation may lead to manufacturing and assembly issues that may result in poor yields. These issues are driven by substrate non-uniformity and/or high amounts of warpage that are inherent in the organic core based package substrates that are currently being used.

Accordingly, embodiments disclosed herein may include a package substrate with a glass interposer architecture. In some embodiments, first level interconnect (FLI) structures are patterned first through the glass interposer that is provided on a thick carrier. The use of a glass interposer and a thick carrier allows for improved substrate uniformity and a reduction in warpage. After the organic redistribution layers (RDLs) are fabricated over the interposer, the carrier may be patterned to form a frame. The frame will continue to provide stiffness benefits to the package substrate after processing. Further, the frame may be patterned to include interior walls. The interior walls can also help prevent thermal cross-talk between the dies that are mounted to the interposer. This may improve thermal performance of the package substrate as well. Such an approach enables continued scaling of organic bridge architectures to bump pitches beyond 25 μm. Further, the improved uniformity and stiffness enables larger form factor devices for future nodes desired for artificial intelligence (AI) modules and/or machine learning (ML) modules where a large number of dies are assembled within a single unit.

In one embodiment, the frame is a glass frame that is adhered to a surface of the glass interposer by a bonding film or an adhesive layer. In other embodiments, the glass frame and the glass interposer are fused together. In such an embodiment, the glass interposer and the glass frame may appear as a single monolithic structure. The surface of the glass interposer opposite from the glass frame may be covered by one or more RDLs. The RDLs may comprise organic dielectric material, such as buildup film or the like. Electrically conductive routing (e.g., pads, traces, vias, etc.) may be embedded within the organic dielectric material in order to electrically couple dies together. The dies may be mounted to the side of the glass interposer with the frame. Vias through the glass interposer electrically couple the dies to the electrically conductive routing of the RDLs on the opposite side of the glass interposer. In another embodiment, an interconnect bridge may be embedded in the RDLs in order to electrically couple the dies together. In an embodiment, the dies may be mounted to the vias with any suitable interconnect structure, such as any FLI structure. For example, the dies may be hybrid bonded to the vias, the dies may be coupled to the vias by solder, or the like.

The use of a glass interposer also allows for simple integration with optical interconnect technologies. For example, an optical waveguide may be embedded within the glass interposer. The optical waveguide may extend to an edge of the glass interposer where a fiber array unit (FAU) or the like is coupled to the package substrate. Accordingly, high bandwidth optical signaling may be used in order to communicatively couple different systems together.

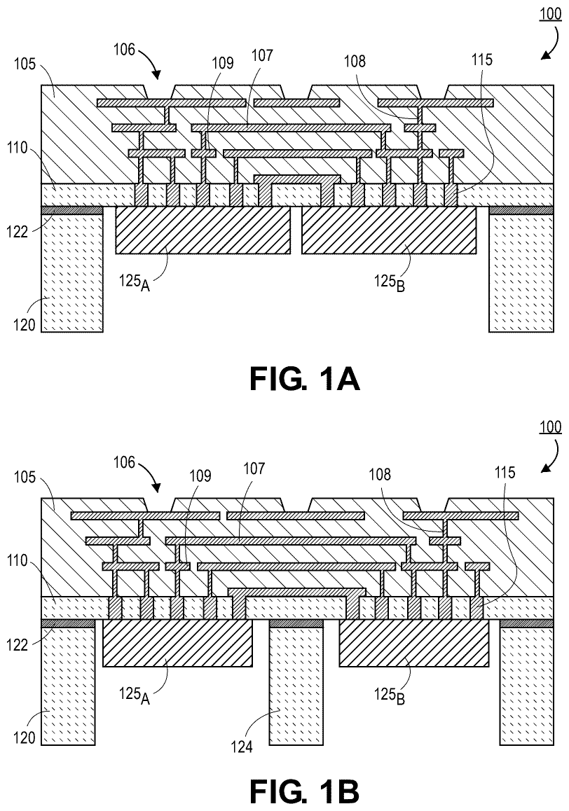

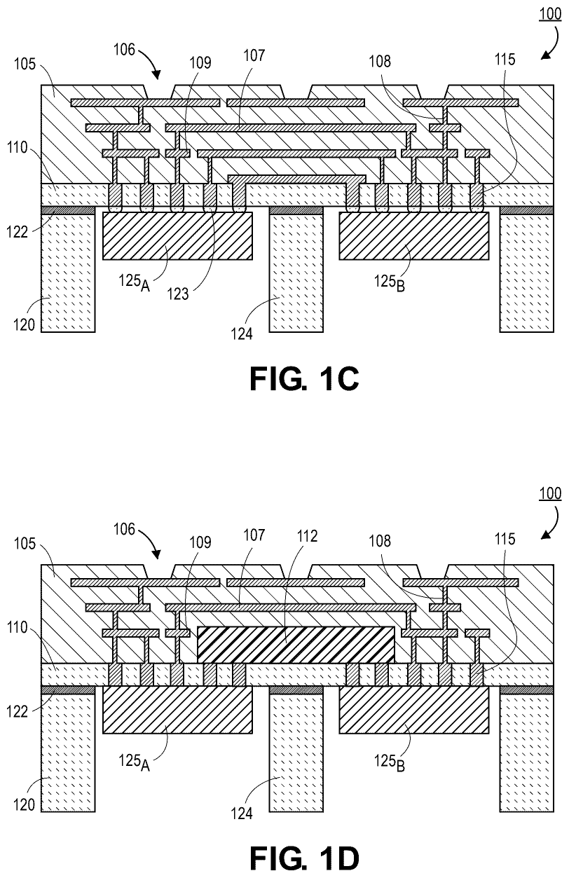

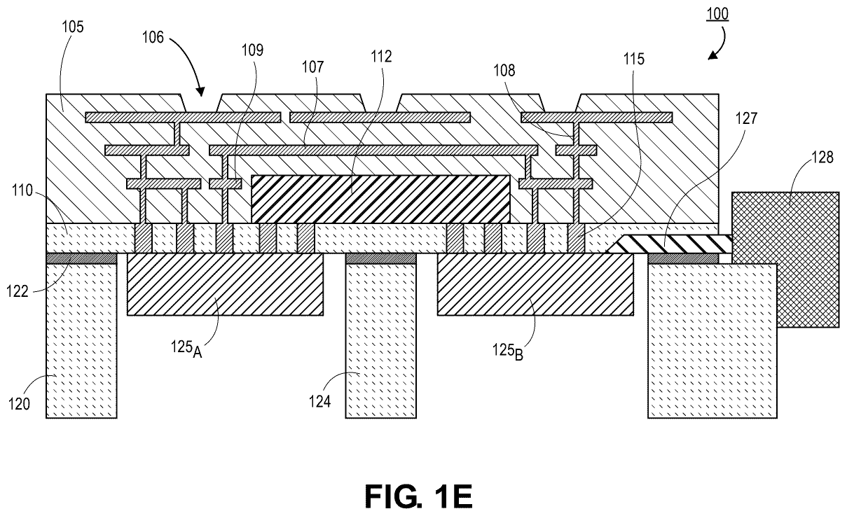

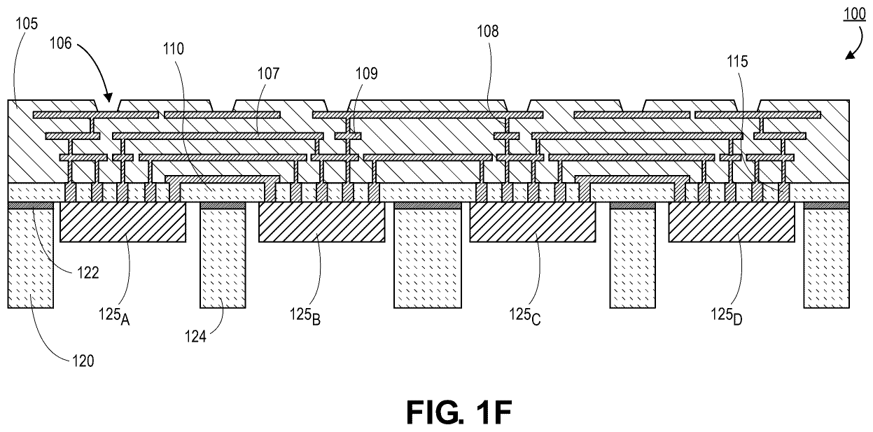

Referring now to FIGS. 1A-1F, a series of cross-sectional illustrations depicting package substrates 100 with glass interposers 110 and a reinforcement frame 120 is shown, in accordance with various embodiments.

Referring now to FIG. 1A, a cross-sectional illustration of a package substrate 100 is shown, in accordance with an embodiment. In an embodiment, the package substrate 100 comprises an interposer 110 with a plurality of vias 115 that pass through a thickness of the interposer 110. The vias 115 may comprise copper vias or the like. In the illustrated embodiment, the vias 115 have a substantially rectangular cross-sectional shape. Though, in other embodiments the vias 115 may have tapered sidewalls or an hourglass shaped cross-section. The vias 115 may be formed with any suitable process. In some embodiments, a laser assisted etching process is used to pattern holes through the interposer 110, and the vias 115 are plated in the holes.

In an embodiment, the interposer 110 may comprise a glass layer. The interposer 110 may be substantially all glass. The interposer 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, interposer 110 may be distinguished from, for example, the “prepreg” or “FR4” core of a Printed Circuit Board (PCB) substrate which typically comprises glass fibers embedded in a resinous organic material, such as an epoxy.

The interposer 110 may have any suitable dimensions. In a particular embodiment, the interposer 110 may have a thickness that is approximately 50 μm or greater. For example, the thickness of the interposer 110 may be between approximately 50 μm and approximately 1.4 mm. Though, smaller or larger thicknesses may also be used. The interposer 110 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the interposer 110 (from an overhead plan view) may be between approximately 10 mm×10 mm and approximately 250 mm×250 mm. In an embodiment, the interposer 110 may have a first side that is perpendicular or orthogonal to a second side. In a more general embodiment, the interposer 110 may comprise a rectangular prism volume with sections (e.g., vias) removed and filled with other materials (e.g., metal, etc.).

The interposer 110 may comprise a single monolithic layer of glass. In other embodiments, the interposer 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the interposer 110 may each have a thickness less than approximately 50 μm. For example, discrete layers of glass in the interposer 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The interposer 110 may be any suitable glass formulation that has the necessary mechanical robustness and compatibility with semiconductor packaging manufacturing and assembly processes. For example, the interposer 110 may comprise aluminosilicate glass, borosilicate glass, alumino-borosilicate glass, silica, fused silica, or the like. In some embodiments, the interposer 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the interposer 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the interposer 110 may comprise at least 23 percent silicon (by weight) and at least 26 percent oxygen (by weight). In some embodiments, the interposer 110 may further comprise at least 5 percent aluminum (by weight).

In an embodiment, a frame 120 may be provided over a surface of the interposer 110. For example, the frame 120 is provided over the bottom surface of the interposer 110 in FIG. 1A. The frame 120 may be adhered to the interposer 110 by an adhesive layer 122. The adhesive layer 122 may be a material that provides strong adhesion between the interposer 110 and the frame 120, while also being resistant to an etching process that is used to form the frame 120 (as will be described in greater detail below). In an embodiment, the frame 120 may comprise a glass material. For example, the glass material for the frame 120 may be similar to any of the glass materials described in greater detail herein with respect to the interposer 110.

The frame 120 may comprise a ring shaped structure that is provided proximate to a perimeter of the interposer 110. In the illustrated embodiment, the outer edge of the frame 120 is substantially coplanar with the outer edge of the interposer 110. Though, in other embodiments, the frame 120 may have an outer edge that is outside of a footprint of the interposer 110, or the frame 120 may have an outer edge that is set in from the edge of the interposer 110.

In an embodiment, the frame 120 provides additional stiffness to the package substrate 100. As such, warpage induced by coefficient of thermal expansion (CTE) mismatches between materials of the package substrate 100 may be mitigated or substantially eliminated. In an embodiment, increasing the thickness of the frame 120 may provide improved warpage reduction. The thickness of the frame 120 may be greater than a thickness of the interposer 110 in some embodiments. Reducing warpage is one of the enablers for shrinking the interconnect pitch for the dies 125A and 125B. For example, extremely flat surfaces are desired for hybrid bonding interconnects, such as the hybrid bonding between the dies 125A-125B and the vias 115.

In an embodiment, an RDL 105 is provided over a surface of the interposer 110 opposite from the frame 120. The RDL 105 may comprise an organic dielectric material, such as a buildup film or the like. The RDL 105 may also comprise electrically conductive routing (e.g., pads 109, vias 108, traces 107, etc.). While a single monolithic RDL 105 is shown in FIG. 1A, it is to be appreciated that the RDL 105 may comprise a plurality of different individual layers that are laminated over each other. Openings 106 may be provided at the top of the RDL 105 to enable solder connections or the like.

In an embodiment, the electrically conductive routing may provide electrical coupling between a first die 125A and a second die 125B. For example, electrically conductive features in the RDL 105 may be electrically coupled to the vias 115, which in turn are electrically coupled to the first die 125A and the second die 125B. Further, the high planarity of the interposer 110 and/or the reduced warpage due to the frame 120 allows for fine pitch die-to-die connections can be made.

Referring now to FIG. 1B, a cross-sectional illustration of a package substrate 100 is shown, in accordance with an additional embodiment. In an embodiment, the package substrate 100 in FIG. 1B is similar to the package substrate 100 in FIG. 1A, with the exception of the frame 120. In addition to the outer walls of the frame 120 around a perimeter of the interposer 110, an interior wall 124 may be provided as part of the frame 120. The interior wall 124 may extend across the interposer 110 from one outer wall of the frame 120 to a second outer wall of the frame on the opposite side of the interposer 110. That is, the interior wall 124 in FIG. 1B is coupled to portions of the frame 120 outside of the plane of FIG. 1B.

The additional interior wall 124 may improve the mechanical robustness of the package substrate 100. As such, warpage may be further reduced and/or eliminated. Additionally, the interior wall 124 may provide thermal benefits to the package substrate 100. For example, the interior wall 124 may minimize or prevent thermal cross-talk between the first die 125A and the second die 125B. For example, the thickness of the frame 120 (including the interior wall 124) may be such that substantially an entire thickness of the first die 125A and the second die 125B is overlapped by a portion of the frame 120 or the interior wall 124. Though, the adhesive layer 122 may also overlap a portion of the thickness of the first die 125A and the second die 125B in some embodiments.

Referring now to FIG. 1C, a cross-sectional illustration of a package substrate 100 is shown, in accordance with an additional embodiment. In an embodiment, the package substrate 100 in FIG. 1C is similar to the package substrate 100 in FIG. 1B, with the exception of the interconnects between the dies 125A-125B and the vias 115. Instead of a hybrid bond, the dies 125A-125B may be coupled to the vias 115 with any suitable FLI architecture. For example, in FIG. 1C, the interconnects may comprise solder balls 123 or the like.

Referring now to FIG. 1D, a cross-sectional illustration of a package substrate 100 is shown, in accordance with an additional embodiment. In an embodiment, the package substrate 100 in FIG. 1D is similar to the package substrate 100 in FIG. 1C, with the exception of the RDL 105. Instead of electrically coupling the first die 125A to the second die 125B with vias 108, pads 109, and traces 107 within the RDL 105, a bridge 112 may be used. The bridge 112 may be embedded within the RDL 105. For example, the bridge 112 may be provided on the top surface of the interposer 110. In the illustrated embodiment, the bridge 112 is hybrid bonded to the vias 115. Though, any suitable interconnect architecture may be used between the bridge 112 and the vias 115. The planarity of the interposer 110 enables fine pitch interconnects to the bridge 112.

In an embodiment, the bridge 112 may comprise any sort of interconnect bridge architecture. For example, the bridge 112 may comprise a silicon bridge, a glass bridge, or the like. Electrically conductive traces (not shown) may be integrated into the bridge 112 in order to provide the electrical coupling between the first die 125A and the second die 125B.

Referring now to FIG. 1E, a cross-sectional illustration of a package substrate 100 is shown, in accordance with an additional embodiment. In an embodiment, the package substrate 100 in FIG. 1E is similar to the package substrate 100 in FIG. 1D, with the exception of the structure of the interposer 110. Particularly, the interposer 110 may further comprise an optical waveguide 127. Since the interposer 110 comprises glass, the optical waveguide 127 may be embedded directly within the interposer 110. The optical waveguide 127 may be optically coupled to one of the dies 125 (i.e., the second die 125B in FIG. 1E). The optical waveguide 127 may extend from the second die 125B to an edge of the interposer 110.

Optical signals from the second die 125B may be coupled into the optical waveguide 127 and propagated to a fiber array unit (FAU) 128 that is coupled to the package substrate 100. The FAU 128 may be optically coupled to different devices (not shown) through optical fibers (not shown) or the like. Optical signals may also be delivered from the FAU 128 to the second die 125B through the optical waveguide 127. The use of optical signaling to/from the package substrate 100 allows for signals to be propagated to devices that are further away (e.g., in a server farm architecture), and/or to provide high bandwidth data transmissions between the package substrate 100 and external devices.

Referring now to FIG. 1F, a cross-sectional illustration of a package substrate 100 is shown, in accordance with an additional embodiment. In an embodiment, the package substrate 100 in FIG. 1F is similar to the package substrate 100 in FIG. 1C, with the exception of being a larger form factor package substrate 100. For example, instead of a pair of dies 125A and 125B, a set of four dies 125A-125D are shown. Though, it is to be appreciated that the stiffness provided by the frame 120 coupled with the planarity of the interposer 110 may allow for package substrates 100 that accommodate eight or more dies 125, sixteen or more dies 125, or thirty two or more dies 125. The ability to form die-to-die interconnects for such a large number of dies 125 allows for package substrates 100 that are suitable for artificial intelligence (AI) module applications and/or machine learning (ML) module applications.

In an embodiment, the presence of such a large number of dies 125 may further complicate thermal control of the package substrate. However, due to the presence of the interior walls 124, thermal cross-talk between neighboring dies 125 is mitigated or eliminated. Particularly, embodiments may include an interior wall 124 between each pair of neighboring dies 125 in some embodiments. The multiple interior walls 124 may also provide improved warpage reduction in some embodiments.

In the illustrated embodiment, the large form factor package substrate 100 includes die-to-die interconnects that are provided by electrical routing within the RDL 105. However, it is to be appreciated that embedded bridges similar to bridge 112 may also be used in a large form factor package substrate 100. Further, optical routing to/from one or more of the dies 125A-125D may be provided by one or more optical waveguides (not shown) that can be embedded within the interposer 110 (similar to the embodiment shown in FIG. 1E).

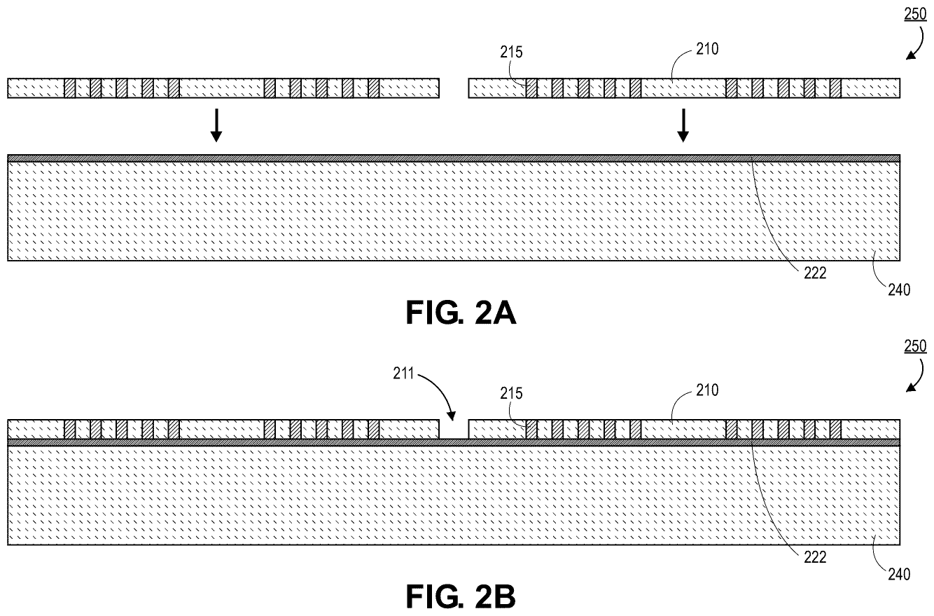

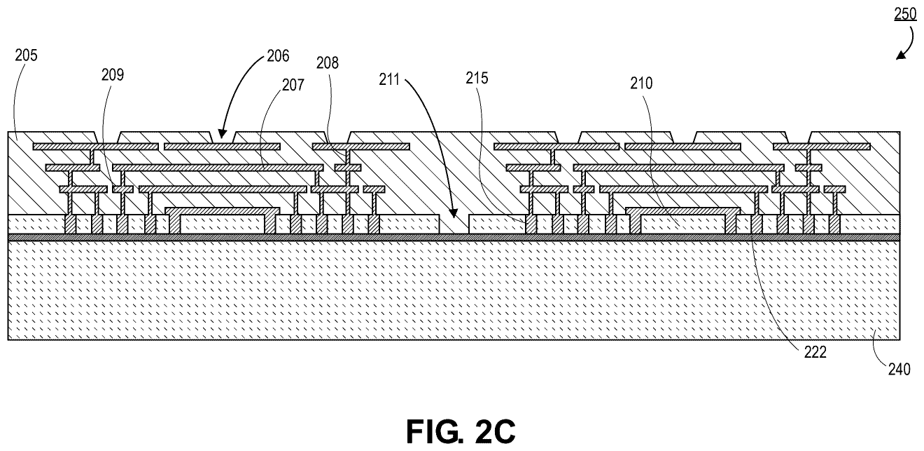

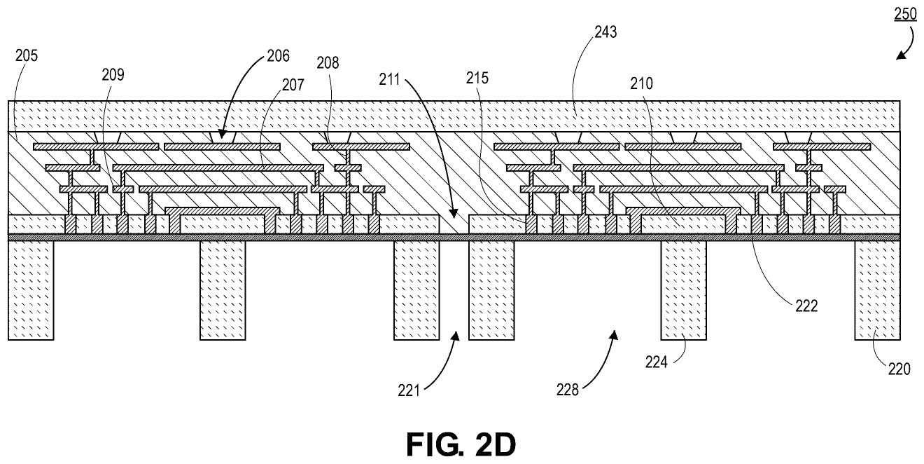

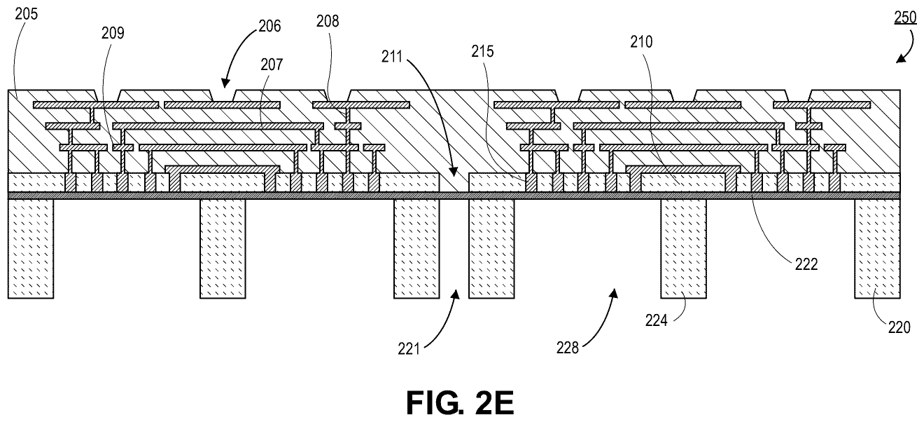

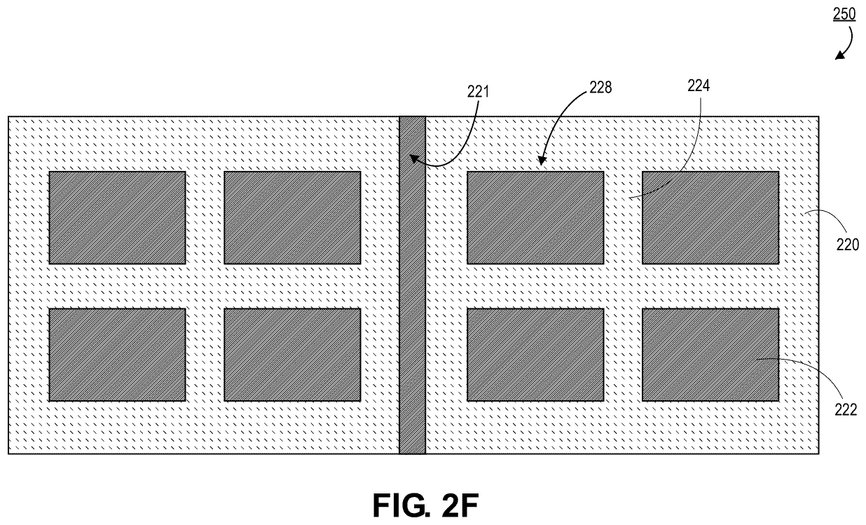

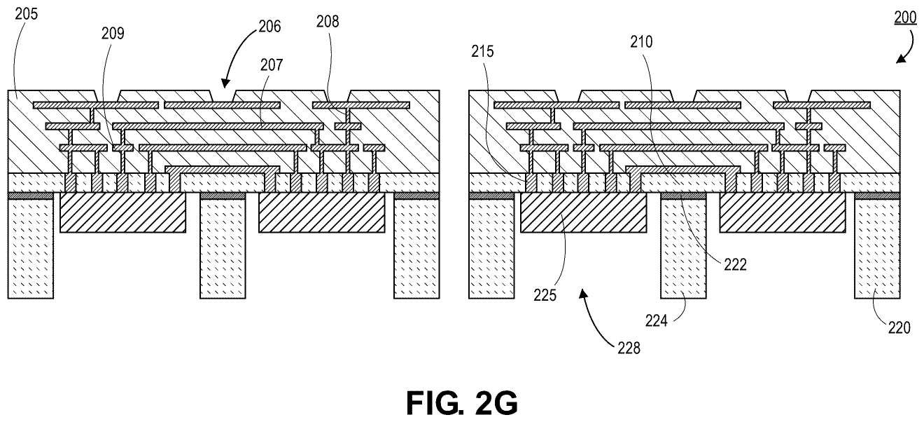

Referring now to FIGS. 2A-2G, a series of illustrations depicting a process for forming a package substrate 200 with a glass interposer 210 and a frame 220 is shown, in accordance with an embodiment. In the illustrated embodiment, the package substrate 200 is similar to the package substrate 100 in FIG. 1B. Though, it is to be appreciated that modifications to the process may be implemented in order to provide a package substrate 200 similar to any of the package substrates 100 described with respect to FIGS. 1A-1F.

Referring now to FIG. 2A, a cross-sectional illustration of a panel 250 at a stage of manufacture is shown, in accordance with an embodiment. In an embodiment, the panel 250 may comprise a carrier 240. The carrier 240 may comprise a glass layer that is similar to any of the glass layers described in greater detail herein. In an embodiment, an adhesive layer 222 may be provided across a top surface of the carrier 240.

As indicated by the arrows one or more interposers 210 may be attached to the carrier 240. The interposers 210 may comprise a glass layer that is similar to any of the glass layers described in greater detail herein. A plurality of vias 215 may be provided through a thickness of each of the interposers 210. The interposer 210 may be similar to the interposer 110 described in greater detail herein, and the vias 215 may be similar to the vias 115 described in greater detail herein.

Referring now to FIG. 2B, a cross-sectional illustration of the panel 250 after the interposers 210 are adhered to the carrier 240 by the adhesive layer 222 is shown, in accordance with an embodiment. In an embodiment, the interposers 210 may be spaced apart from each other by a gap 211. The gap 211 allows for a subsequent singulation process that does not need to cut through the interposers 210. As such, the probability of cracking or otherwise damaging the interposers 210 is reduced.

Referring now to FIG. 2C, a cross-sectional illustration of the panel 250 after an RDL 205 is formed over a surface of the interposers 210 opposite from the carrier 240 is shown, in accordance with an embodiment. In an embodiment, the RDL 205 may comprise an organic dielectric material, such as a buildup film or the like. A plurality of individual layers may be laminated over each other in order to form the RDL 205. In an embodiment, electrically conductive routing (e.g., pads 209, vias 208, traces 207, etc.) may be integrated into the RDL 205 as well. The electrically conductive routing may be fabricated with traditional electronic packaging fabrication processes. In an embodiment, openings 206 may be fabricated into a top surface of the RDL 205 in order to prove locations for solder (not shown) for forming interconnects to an additional substrate (such as a board) in a subsequent processing operation.

Referring now to FIG. 2D, a cross-sectional illustration of the panel 250 after the carrier 240 is patterned in order to form openings 228 that define a frame 220 is shown, in accordance with an embodiment. In an embodiment, a second carrier 243 may be applied over the RDL 205 prior to the patterning process. The second carrier 243 may comprise a glass layer, a silicon layer, a metallic layer, or the like. While a second carrier 243 is shown in FIG. 2D, some embodiments may pattern the carrier 240 without the use of the second carrier 243.

In an embodiment, the carrier 240 may be patterned with an etching process. For example, a patterned resist layer (not shown) may be applied over the carrier 240 in order to selectively etch away portions of the carrier 240 to form the frame 220 and the interior walls 224. In an embodiment, an opening 221 may also be patterned into the frame 220. The opening 221 may be positioned above the gap 211. As such, the subsequent singulation process may not need to pass through the glass of the frame 220.

In an embodiment, the adhesive layer 222 may comprise a material that is resistant to the etching chemistry used to remove portions of the carrier 240. Accordingly, the etching process will not negatively impact the underlying interposer 210. In the illustrated embodiment, the sidewalls of the frame 220 and the interior wall 224 are substantially vertical. Though, in some embodiments, the etching process may result in a frame 220 that comprise tapered or curved sidewalls.

In an embodiment, the interior wall 224 may separate the vias 215 into a first group of vias 215 and a second group of vias 215. The first group of vias 215 may be coupled to a first die in a subsequent processing operation, and the second group of vias 215 may be coupled to a second die in a subsequent processing operations. That is, the interior wall 224 may be provided between the pair of dies added in a subsequent processing operation.

Referring now to FIG. 2E, a cross-sectional illustration of the panel 250 after the second carrier 243 is removed is shown, in accordance with an embodiment. In an embodiment, the second carrier 243 may be removed with any suitable process. Removal of the second carrier 243 exposes the RDL 205 again.

Referring now to FIG. 2F, a plan view illustration of the panel 250 in FIG. 2E is shown, in accordance with an embodiment. As shown, the opening 221 extends across the panel 250 in order to define a pair of frames 220. The outer edges of the openings 228 may include a portion of the outer wall of the frame 220, and the interior edges of the openings 228 may include a portion of the interior wall 224. In the illustrated embodiment, a pair of interior walls 224 within each frame 220 form a cross. This defines four openings 228. Though, it is to be appreciated that any number of interior walls 224 may be used in order to provide a desired number of openings 228. In some embodiments, a die (not shown) may ultimately be placed in each opening 228. Though, some embodiments may include two or more dies within each opening 228. As shown, in FIG. 2F, the adhesive layer 222 remains at the bottom of the openings 228 and the opening 221 in order to protect the underlying interposer 210 (not visible in FIG. 2F) from the etching process.

Referring now to FIG. 2G, a cross-sectional illustration of the panel 250 after exposed portions of the adhesive layer 222 are removed, dies 225 are mounted to the interposer 210, and a singulation process is used to form individual package substrates 200 is shown, in accordance with an embodiment. After the frame 220 and interior walls 224 are formed, a second etching process may be used to selectively remove the adhesive layer 222. The removal of the adhesive layer 222 exposes the vias 215. The dies 225 may then be attached to the interposer 210. For example, the dies 225 may be hybrid bonded to the vias 215 within the interposer 210. The vias 215 and the electrical routing within the RDL 205 may electrically couple dies 225 within a single package substrate 200 together.

In an embodiment, the panel 250 may be singulated along the opening 221 and the gap 211. The singulation process may include a mechanical sawing process, a laser ablation process, or the like. Since the glass of the interposer 210 is spaced outside of the gap 211 and the opening 221 is provided between the frames 220, the singulation process may not need to pass through any glass layers. This simplifies the singulation process and minimizes potential damage to the package substrate 200.

In the illustrated embodiment, the singulation process completely removes a portion of the RDL 205 along sidewalls of the interposers 210. Though, in other embodiments, a portion of the RDL 205 may remain along the sidewall of the interposer 210. As such, the package substrate 200 may comprise one or more edges that have an interposer 210 coated with an organic dielectric material, such as a portion of the RDL 205.

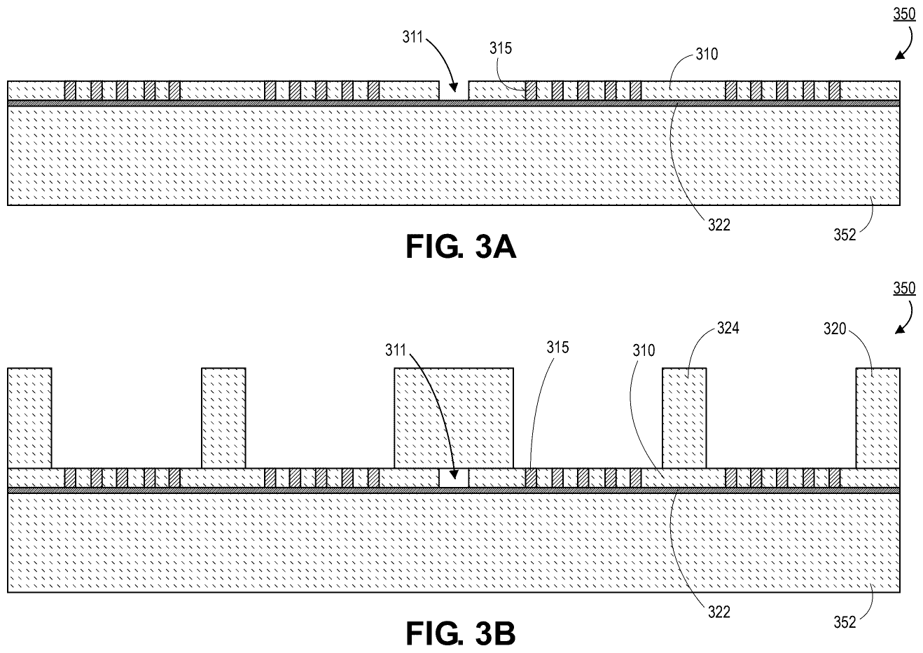

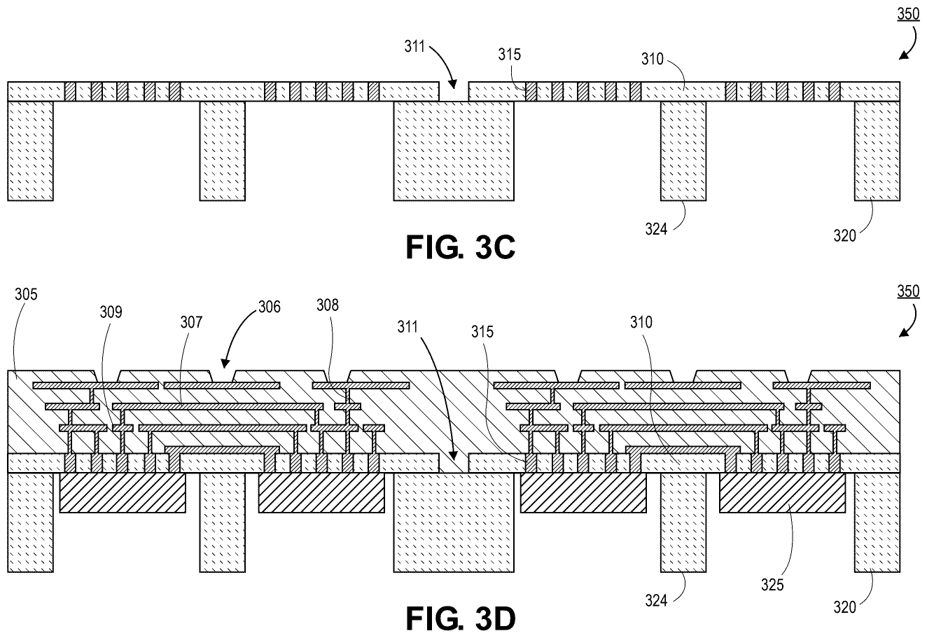

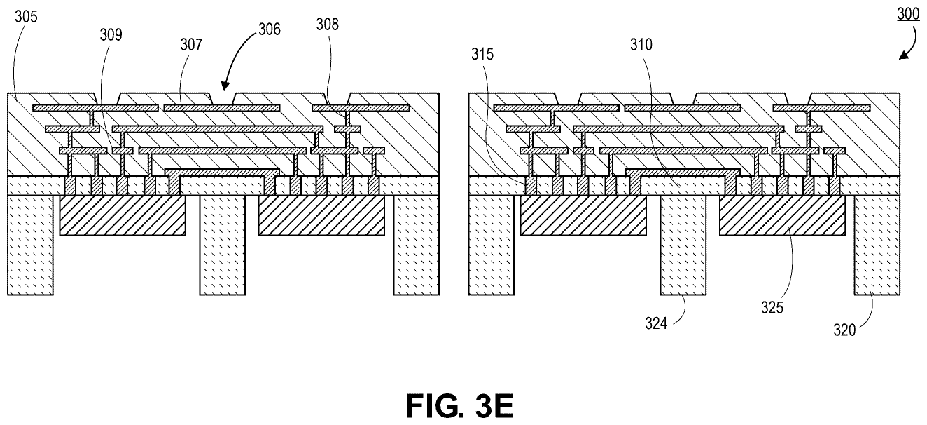

Referring now to FIGS. 3A-3E, a series of cross-sectional illustrations depicting a process for forming a package substrate 300 with a glass interposer 310 and a frame 320 is shown, in accordance with an additional embodiment. In an embodiment, the process in FIGS. 3A-3E relies on a fusion bonding process between the interposer 310 and the frame 320 instead of an adhesive layer.

Referring now to FIG. 3A, a cross-sectional illustration of a panel 350 at a stage of manufacture is shown, in accordance with an embodiment. In an embodiment, the panel 350 may comprise a carrier 352. The carrier 352 may comprise a glass layer, a silicon layer, a metal layer, or the like. In an embodiment, an adhesive layer 322 may be provided across a top surface of the carrier 352.

In an embodiment, one or more interposers 310 may be attached to the carrier 352. The interposers 310 may comprise a glass layer that is similar to any of the glass layers described in greater detail herein. In an embodiment, the interposers 310 may be spaced apart from each other by a gap 311. The gap 311 allows for a subsequent singulation process that does not need to cut through the interposers 310. As such, the probability of cracking or otherwise damaging the interposers 310 is reduced. A plurality of vias 315 may be provided through a thickness of each of the interposers 310. The interposer 310 may be similar to the interposer 110 described in greater detail herein, and the vias 315 may be similar to the vias 115 described in greater detail herein.

Referring now to FIG. 3B, a cross-sectional illustration of the panel 350 after a frame 320 is attached to the interposers 310 is shown, in accordance with an embodiment. In an embodiment, the frames 320 may be preformed. That is, there may not be a need to etch the frames 320 after the frames 320 are attached to the interposers 310. The frames 320 may also comprise interior walls 324 in some embodiments. The frames 320 may comprise a glass material that is similar to any of the glass materials described in greater detail herein.

As shown in FIG. 3B, a single monolithic frame 320 is attached to all of the interposers 310. For example, a portion of the frame 320 may span across the gap 311. Such a monolithic structure allows for a single placement operation. Though, in other embodiments, individual frames 320 may be placed over each of the interposers 310.

In an embodiment, the frame 320 may be fused to the interposers 310. While a seam between the interposers 310 and the frame 320 is shown in FIG. 3B, it is to be appreciated that the fusing process may result in a seamless connection between the interposers 310 and the frame 320. Accordingly, the resulting combination of the interposer 310 and the frame 320 may be seen as a single monolithic structure in some embodiments.

Referring now to FIG. 3C, a cross-sectional illustration of the panel 350 after the carrier 352 is removed is shown, in accordance with an embodiment. The carrier 352 and the adhesive layer 322 may be removed with any suitable process. Removal of the carrier 352 and the adhesive layer 322 exposes a surface of the interposer 310 and the vias 315.

Referring now to FIG. 3D, a cross-sectional illustration of the panel 350 after an RDL 305 is formed over the interposers 310 and dies 325 are attached to the interposers 310 is shown, in accordance with an embodiment. In an embodiment, the RDL 305 may comprise an organic dielectric material, such as a buildup film or the like. A plurality of individual layers may be laminated over each other in order to form the RDL 305. In an embodiment, electrically conductive routing (e.g., pads 309, vias 308, traces 307, etc.) may be integrated into the RDL 305 as well. The electrically conductive routing may be fabricated with traditional electronic packaging fabrication processes. In an embodiment, openings 306 may be fabricated into a top surface of the RDL 305 in order to prove locations for solder (not shown) for forming interconnects to an additional substrate (such as a board) in a subsequent processing operation.

In an embodiment, the dies 325 may be attached to the interposer 310 with any suitable process. For example, the dies 325 may be hybrid bonded to the vias 315 within the interposer 310. The vias 315 and the electrical routing within the RDL 305 may electrically couple dies 325 within a single package substrate 300 together.

Referring now to FIG. 3E, a cross-sectional illustration of the panel 350 after singulation to form a plurality of package substrate 300 is shown, in accordance with an embodiment. In an embodiment, the panel 350 may be singulated along the gap 311. The singulation process may include a mechanical sawing process, a laser ablation process, or the like. Since the glass of the interposer 310 is spaced outside of the gap 311, the singulation process may not need to pass through the glass of the interposers 310. This simplifies the singulation process and minimizes potential damage to the package substrate 300.

In the illustrated embodiment, the singulation process completely removes a portion of the RDL 305 along sidewalls of the interposers 310. Though, in other embodiments, a portion of the RDL 305 may remain along the sidewall of the interposer 310. As such, the package substrate 300 may comprise one or more edges that have an interposer 310 coated with an organic dielectric material, such as a portion of the RDL 305.

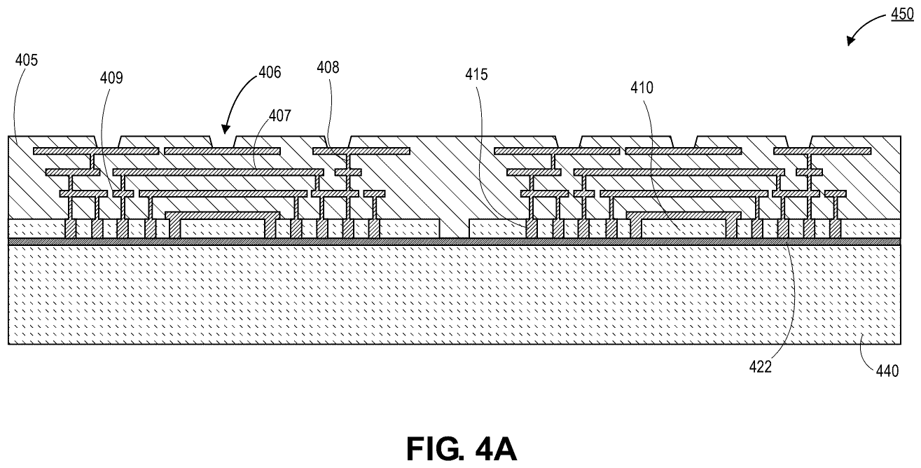

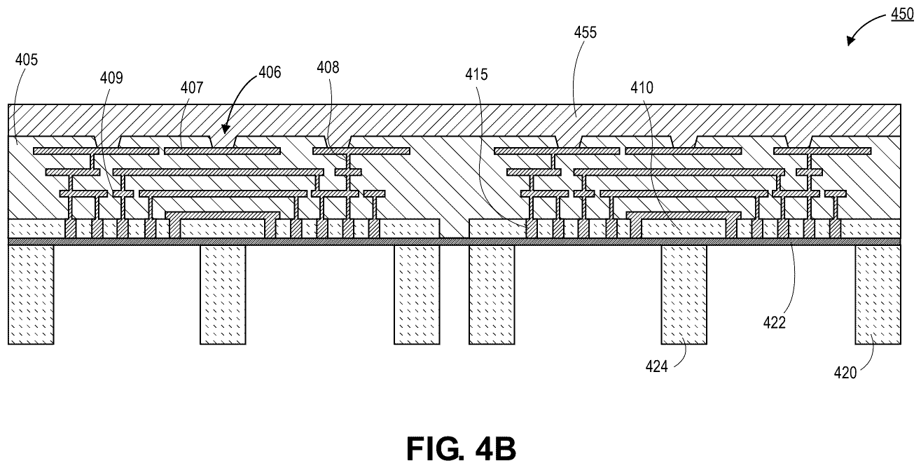

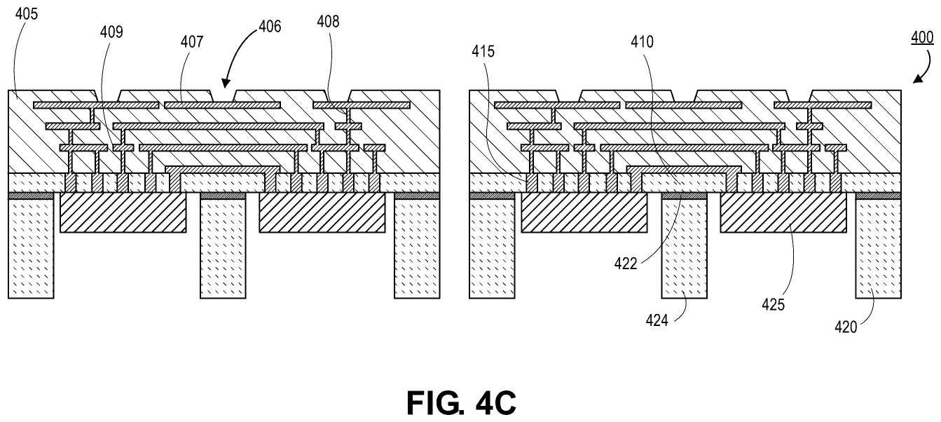

Referring now to FIGS. 4A-4C, a series of cross-sectional illustrations depicting a process for forming a package substrate 400 with a glass interposer and a frame 420 is shown, in accordance with an additional embodiment.

Referring now to FIG. 4A, a cross-sectional illustration of a panel 450 at a stage of manufacture is shown, in accordance with an embodiment. In an embodiment, the panel 450 may be fabricated with processes similar to those described in greater detail herein with respect to FIGS. 2A-2C. For example, the panel 450 may comprise a carrier 440 that is bonded to a plurality of interposers 410 by an adhesive layer 422. The interposers 410 may comprise a plurality of vias 415. Additionally, an RDL 405 with electrical routing (e.g., pads 409, vias 408, traces 407, etc.) may be provided over the interposer 410 on a surface of the interposer 410 opposite from the carrier 440. Openings 406 for interconnects (not shown) may also be provided at the top of the RDL 405.

Referring now to FIG. 4B, a cross-sectional illustration of the panel 450 after an etching process is used to pattern the carrier 440 into a frame 420 with interior walls 424 is shown, in accordance with an embodiment. In an embodiment, the carrier 440 may be patterned with an etching process. In order to protect the RDL 405 from the etching process, a protective film 455 is applied over the RDL 405. The protective film 455 may include any suitable resist material, such as polyethylene terephthalate (PET) or the like.

Referring now to FIG. 4C, a cross-sectional illustration of the panel 450 after exposed portions of the adhesive layer 422 are removed, dies 425 are coupled to the interposer 410, and the panel 450 is singulated into individual package substrates 400 is shown, in accordance with an embodiment. After the frame 420 and interior walls 424 are formed, a second etching process may be used to selectively remove the adhesive layer 422. The removal of the adhesive layer 422 exposes the vias 415. The protective film 455 may also be removed. In an embodiment, the dies 425 may then be attached to the interposer 410. For example, the dies 425 may be hybrid bonded to the vias 415 within the interposer 410. The vias 415 and the electrical routing within the RDL 405 may electrically couple dies 425 within a single package substrate 400 together.

In an embodiment, the panel 450 may be singulated between the interposers 410. The singulation process may include a mechanical sawing process, a laser ablation process, or the like. Since the cut line of the singulation is outside of the glass of the interposer 410 and an opening is provided between the frames 420, the singulation process may not need to pass through any glass layers. This simplifies the singulation process and minimizes potential damage to the package substrate 400.

In the illustrated embodiment, the singulation process completely removes a portion of the RDL 405 along sidewalls of the interposers 410. Though, in other embodiments, a portion of the RDL 405 may remain along the sidewall of the interposer 410. As such, the package substrate 400 may comprise one or more edges that have an interposer 410 coated with an organic dielectric material, such as a portion of the RDL 405.

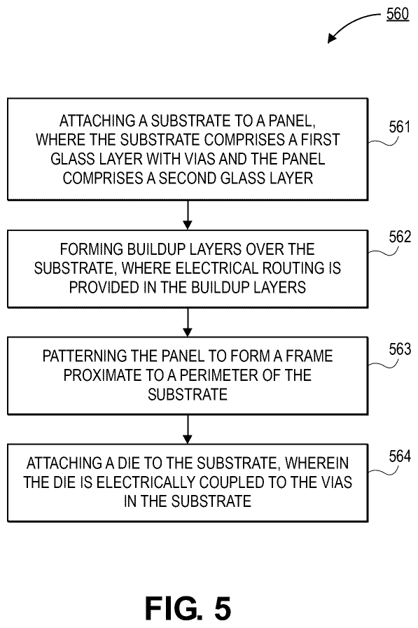

Referring now to FIG. 5, a flow diagram of a process 560 for forming a package substrate with a glass interposer and a frame is shown, in accordance with an embodiment. In an embodiment, the process 560 may be used to form a package substrate similar to any of the package substrates described herein that include an adhesive layer between the interposer and the frame.

In an embodiment, the process 560 may begin with operation 561, which comprises attaching a substrate to a panel. In an embodiment, the substrate comprises a first glass layer, and vias are formed through a thickness of the substrate. In an embodiment, the panel comprises a second glass layer. In some embodiments, the first glass layer and the second glass layer comprise the same or similar glass composition. Though, other embodiments may include different glass compositions for the substrate and the panel. In an embodiment, the substrate is attached to the panel with an adhesive layer or the like.

In an embodiment, the process 560 may continue with operation 562, which comprises forming buildup layers over the substrate. In an embodiment, electrical routing is provided in the buildup layers. The electrical routing may be electrically coupled to the vias that are formed through the substrate.

In an embodiment, the process 560 may continue with operation 563, which comprises patterning the panel to form a frame proximate to a perimeter of the substrate. In an embodiment, the panel may be patterned with an etching process. The buildup layers may be protected during the etching process by a protective film. In some embodiments, a carrier may be attached to the buildup layers to provide additional support during the etching process. In some embodiments, the frame may comprise one or more interior walls.

In an embodiment, the process 560 may continue with operation 564, which comprises attaching a die to the substrate. In an embodiment, the die is electrically coupled to the vias in the substrate. The die may be hybrid bonded to the vias, or the die may be coupled to the vias by solder interconnects or the like. In some embodiments, two or more dies are coupled to the substrate. In such an embodiment, the electrical routing in the buildup layers may electrically couple the two or more dies together.

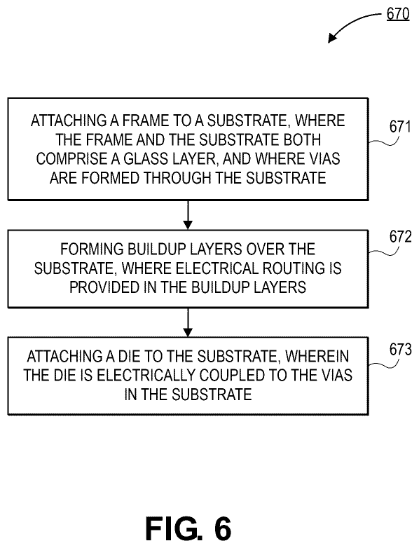

Referring now to FIG. 6, a flow diagram of a process 670 for forming a package substrate with a glass interposer and a frame is shown, in accordance with an embodiment. In an embodiment, the package substrate formed with the process 670 may be similar to any of the package substrates described herein that include a frame that is fused to the interposer.

In an embodiment, the process 670 may begin with operation 671, which comprises attaching a frame to a substrate. In an embodiment, the frame and the substrate comprise a glass layer, and vias are formed through the substrate. In an embodiment, the frame is attached to the substrate with a fusing process. As such, the combination of the frame and the substrate may appear as a monolithic structure without any seams. In an embodiment, the frame may comprise one or more interior walls.

In an embodiment, the process 670 may continue with operation 672, which comprises forming buildup layers over the substrate. In an embodiment, electrical routing is provided in the buildup layers. The electrical routing may be electrically coupled to the vias that are formed through the substrate.

In an embodiment, the process 670 may continue with operation 673, which comprises attaching a die to the substrate. In an embodiment, the die is electrically coupled to the vias in the substrate. The die may be hybrid bonded to the vias, or the die may be coupled to the vias by solder interconnects or the like. In some embodiments, two or more dies are coupled to the substrate. In such an embodiment, the electrical routing in the buildup layers may electrically couple the two or more dies together.

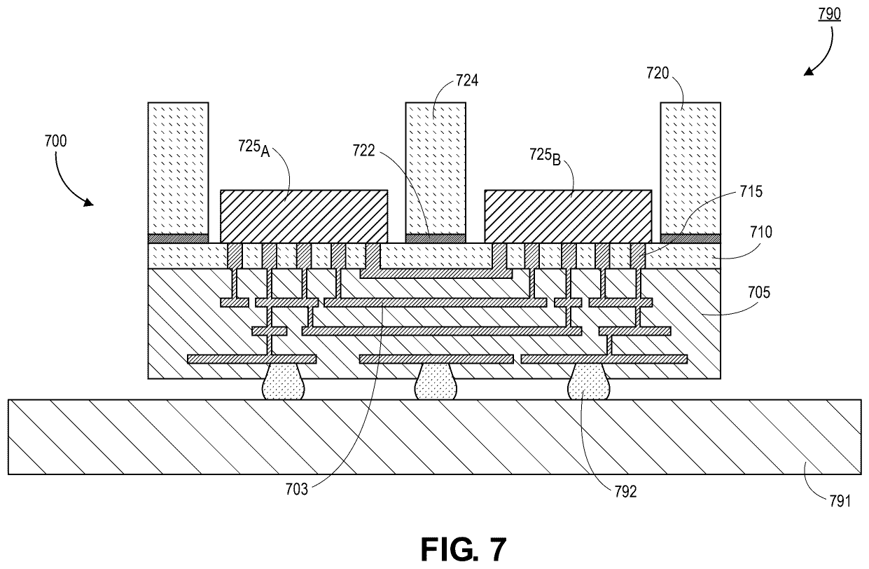

Referring now to FIG. 7, a cross-sectional illustration of an electronic system 790 is shown, in accordance with an embodiment. In an embodiment, the electronic system 790 may comprise a board 791, such as a printed circuit board (PCB), a motherboard, or the like. In an embodiment, the board 791 may be coupled to a package substrate 700 by interconnects 792. The interconnects 792 may include any suitable second level interconnect (SLI) architecture, such as solder balls, sockets, pins, or the like.

In an embodiment, the package substrate 700 may be similar to any of the package substrates described in greater detail herein. For example, the package substrate 700 may comprise a glass interposer 710 with vias 715. An RDL 705 may be provided between the interposer 710 and the board 791. The RDL 705 may comprise electrical routing 703, such as pads, vias, traces, and/or the like. In an embodiment, a frame 720 is coupled to a surface of the interposer 710 opposite from the RDL 705. The frame 720 may also comprise glass. In the illustrated embodiment, the frame 720 is coupled to the interposer 710 by an adhesive layer 722. Though, in other embodiments, the frame 720 may be fused to the interposer 710. The frame 720 may also comprise an interior wall 724 in some embodiments.

In an embodiment, the electronic system 790 may further comprise one or more dies 725 that are coupled to the interposer 710. For example, the dies 725 may be electrically coupled to the vias 715 within the interposer 710 by any suitable FLI architecture. In FIG. 7, the dies 725 are hybrid bonded to the vias 715. In an embodiment, the electrical routing 703 within the RDL 705 may electrically couple the first die 725A to the second die 725B. Additionally, the interior wall 724 may prevent or minimize thermal cross-talk between the first die 725A and the second die 725B. In an embodiment, the dies 725 may include any type of die. For example, the dies 725 may comprise one or more of a processor (e.g., a central processing unit (CPU), a graphics processing unit (GPU), etc.), a memory die, a communications die, and/or the like.

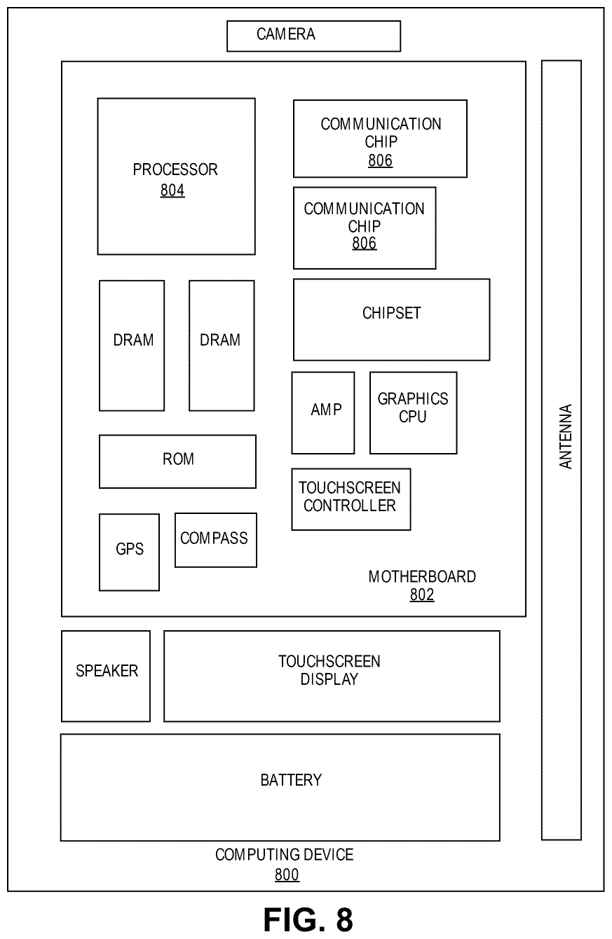

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that comprises a glass interposer with a glass frame, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that comprises a glass interposer with a glass frame, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first substrate, wherein the first substrate comprises a glass layer; a plurality of vias through a through a thickness of the first substrate; a second substrate over a first surface of the first substrate, wherein the second substrate comprises an organic dielectric material; and a frame over a second surface of the first substrate.

Example 2: the apparatus of Example 1, wherein the frame comprises a second glass layer.

Example 3: the apparatus of Example 2, wherein the frame is fused to the first substrate.

Example 4: the apparatus of Examples 1-3, wherein the frame is attached to the first substrate by an adhesive layer.

Example 5: the apparatus of Examples 1-4, further comprising: a first die and a second die over the second surface of the first substrate, wherein the first die and the second die are electrically coupled to the plurality of vias, and wherein the frame surrounds the first die and the second die.

Example 6: the apparatus of Example 5, wherein the second substrate comprises electrical routing that is electrically coupled to the plurality of vias, and wherein the electrical routing electrically couples the first die to the second die.

Example 7: the apparatus of Example 5, further comprising: a bridge embedded in the second substrate, wherein the bridge electrically couples the first die to the second die.

Example 8: the apparatus of Examples 5-7, wherein the first die and the second die are hybrid bonded to the plurality of vias.

Example 9: the apparatus of Examples 5-8, wherein the frame comprises an interior wall that is between the first die and the second die.

Example 10: the apparatus of Examples 1-9, further comprising: an optical waveguide in the first substrate.

Example 11: an apparatus, comprising: an interposer with a first thickness, wherein the interposer comprises a glass layer; a plurality of vias through a thickness of the interposer; a frame with a second thickness over a first surface of the interposer, wherein the second thickness is greater than the first thickness; and a redistribution layer (RDL) over a second surface of the interposer.

Example 12: the apparatus of Example 11, wherein the frame forms a ring around the plurality of vias in the interposer.

Example 13: the apparatus of Example 12, wherein the frame further comprises an interior wall, and wherein the interior wall divides the plurality of vias in the interposer into a first group of vias and a second group of vias.

Example 14: the apparatus of Examples 11-13, wherein the frame comprises glass.

Example 15: the apparatus of Example 14, wherein the frame is fused to the interposer.

Example 16: the apparatus of Examples 11-15, further comprising: a first die and a second die electrically coupled to the plurality of vias over the first surface of the interposer; and a board coupled to the RDL.

Example 17: an apparatus, comprising: an interposer, wherein the interposer comprises a glass layer; a plurality of vias through a thickness of the interposer; a plurality of dies over a first surface of the interposer, wherein the plurality of dies are electrically coupled to the plurality of vias; a frame over the first surface of the interposer, wherein the frame comprises a plurality of walls, and wherein neighboring ones of the plurality of dies are separated from each other by one of the plurality of walls; and a redistribution layer (RDL) over a second surface of the interposer, wherein the RDL electrically couples two or more of the plurality of dies together.

Example 18: the apparatus of Example 17, wherein the frame comprises a second glass layer.

Example 19: the apparatus of Example 17 or Example 18, wherein the apparatus is an artificial intelligence (AI) module and/or a machine learning (ML) module.

Example 20: the apparatus of Examples 17-19, further comprising: a board coupled to the RDL.

What is claimed is:

1. An apparatus, comprising:
a first substrate, wherein the first substrate comprises a glass layer;
a plurality of vias through a through a thickness of the first substrate;
a second substrate over a first surface of the first substrate, wherein the second substrate comprises an organic dielectric material; and
a frame over a second surface of the first substrate.

2. The apparatus of claim 1, wherein the frame comprises a second glass layer.

3. The apparatus of claim 2, wherein the frame is fused to the first substrate.

4. The apparatus of claim 1, wherein the frame is attached to the first substrate by an adhesive layer.

5. The apparatus of claim 1, further comprising:
a first die and a second die over the second surface of the first substrate, wherein the first die and the second die are electrically coupled to the plurality of vias, and wherein the frame surrounds the first die and the second die.

6. The apparatus of claim 5, wherein the second substrate comprises electrical routing that is electrically coupled to the plurality of vias, and wherein the electrical routing electrically couples the first die to the second die.

7. The apparatus of claim 5, further comprising:
a bridge embedded in the second substrate, wherein the bridge electrically couples the first die to the second die.

8. The apparatus of claim 5, wherein the first die and the second die are hybrid bonded to the plurality of vias.

9. The apparatus of claim 5, wherein the frame comprises an interior wall that is between the first die and the second die.

10. The apparatus of claim 1, further comprising:
an optical waveguide in the first substrate.

11. An apparatus, comprising:
an interposer with a first thickness, wherein the interposer comprises a glass layer;
a plurality of vias through a thickness of the interposer;
a frame with a second thickness over a first surface of the interposer, wherein the second thickness is greater than the first thickness; and
a redistribution layer (RDL) over a second surface of the interposer.

12. The apparatus of claim 11, wherein the frame forms a ring around the plurality of vias in the interposer.

13. The apparatus of claim 12, wherein the frame further comprises an interior wall, and wherein the interior wall divides the plurality of vias in the interposer into a first group of vias and a second group of vias.

14. The apparatus of claim 11, wherein the frame comprises glass.

15. The apparatus of claim 14, wherein the frame is fused to the interposer.

16. The apparatus of claim 11, further comprising:
a first die and a second die electrically coupled to the plurality of vias over the first surface of the interposer; and
a board coupled to the RDL.

17. An apparatus, comprising:
an interposer, wherein the interposer comprises a glass layer;
a plurality of vias through a thickness of the interposer;
a plurality of dies over a first surface of the interposer, wherein the plurality of dies are electrically coupled to the plurality of vias;
a frame over the first surface of the interposer, wherein the frame comprises a plurality of walls, and wherein neighboring ones of the plurality of dies are separated from each other by one of the plurality of walls; and
a redistribution layer (RDL) over a second surface of the interposer, wherein the RDL electrically couples two or more of the plurality of dies together.

18. The apparatus of claim 17, wherein the frame comprises a second glass layer.

19. The apparatus of claim 17, wherein the apparatus is an artificial intelligence (AI) module and/or a machine learning (ML) module.

20. The apparatus of claim 17, further comprising:
a board coupled to the RDL.
